(19) United States
(12) Patent Application Publication
(10) Pub. No.: US 2006/0264013 A1
(43) Pub. Date: Nov. 23, 2006

(54) Method for implanting ions to a wafer for manufacturing of semiconductor device and method of fabricating graded junction using the same

(75) Inventors: Kyoung Bong Rouh, Gyunggi-do (KR); Seung Woo Jin, Gyunggi-do (KR); Sun Hwan Hwang, Gyunggi-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-shi (KR)

(21) Appl. No.: 11/304,205

(22) Filed: Dec. 14, 2005

(30) Foreign Application Priority Data
May 18, 2005 (KR) 2005-41817

(51) Int. Cl. H01L 21/425

(52) U.S. Cl. 438/514; 438/525; 438/529

(57) ABSTRACT

An ion implantation method for manufacturing a semiconductor device in accordance with present invention is combined ion implantation of vertical ion implantation and tilted ion implantation. In accordance with the above-mentioned ion implantation method, a first dose of impurity ions, as a part of total dose of the impurity ions to be implanted, is first implanted by vertical ion implantation. Then, a remaining dose of impurity ions, except for the first dose from the total dose, is implanted by tilted ion implantation. Herein, tilted ion implantation may be subdivided into a plurality of tilted ion implantation.

### CROSS-REFERENCES TO RELATED APPLICATIONS

The present disclosure relates to subject matter contained in Korean Application No. 10-2005-41817, filed on May 18, 2005, which is herein expressly incorporated by reference its entirety.

### BACKGROUND OF THE INVENTION

The present invention relates to a method for manufacturing a semiconductor device. More specifically, the present invention relates to an ion implantation method for manufacturing a semiconductor device and a method for fabricating graded junctions using the same.

In order to manufacture semiconductor devices, in particular semiconductor memory devices such as dynamic random access memories (DRAMs), numerous processes are carried out. Such processes include laminating, etching, ion implantation, etc., and are usually conducted on the basis of a wafer unit. Among these unit processes, ion implantation is a process in which dopant ions such as boron and arsenic are accelerated by a strong electric field and are then passed through wafer surfaces. Therefore, electrical properties of materials can be modified via such ion implantation.

FIG. 1 is a view illustrating vertical ion implantation as one example of conventional ion implantation. A wafer 100 is supported by a wafer support 110. The wafer support 110 may be arranged such that it is tilted to the right or left by a rotation axis 120. The rotation axis 120 is supported by a shaft 130. The wafer 100 is arranged so as to expose a front surface 101, to which impurity ions are implanted via a wafer support assembly. Impurity ions 200 are implanted into the front surface 101 of the wafer 100, as indicated by arrows in FIG. 1. Herein, as indicated by a dotted line, the angle between an implantation path of the impurity ions 200 and a vertical line relative to the front surface 101 of the wafer 100 is zero degrees.

An impurity region formed using vertical ion implantation has low sheet resistance. The vertical implantation involves injecting ions to enter the surface of the wafer, such that the angle of incidence is substantially orthogonal to the surface of the wafer. Recently, however, the extreme increase of integration of semiconductor devices has given rise to problems relating to adverse channeling effects. Channeling effects are phenomena exhibiting Gaussian profiles when the profiles of impurity ions are not normal, such as during implantation of impurity ions to a depth greater than the desired depth after ion implantation. These channeling effects occur more severely as the desired depth control becomes more difficult with increased integration of the semiconductor devices. Therefore tilted ion implantation, which is capable of inhibiting such channeling effects, is currently widely used in the art.

FIG. 2 is a view illustrating a tilted ion implantation method. Hereinafter, like numbers in FIG. 1 refer to like elements in FIG. 2, and therefore a description of the same elements will be omitted. The wafer support 110 is obliquely moved to a predetermined degree about the rotation axis 120. Correspondingly, the wafer 100 is also obliquely positioned to a predetermined degree, and as a result a certain angle (α) is formed between a vertical line relative to the surface of the wafer 100 and the implantation path of the impurity ions 200. That is, vertical ion implantation implants impurity ions in the vertical direction relative to the wafer 100, while tilted ion implantation obliquely implants impurity ions at a specific angle (α) relative to the wafer 100. This angle is the angle defined by a line that is orthogonal to the surface of the wafer and the direction of the ions entering the wafer. The formation of the impurity region via tilted ion implantation inhibits the channeling effects associated with the vertical ion implantation process.

FIG. 3 is a graph showing changes in concentrations of impurity ions with respect to junction depths for respective impurity ions implanted according to the vertical ion implantation and tilted ion implantation processes. FIG. 4 is a graph showing changes in sheet resistance and deviation of sheet resistance with respect to temperatures in impurity regions formed according to the vertical ion implantation and tilted ion implantation processes, respectively.

FIG. 3 illustrates the results of Secondary Ion Mass Spectroscopy (SIMS) detection of the impurity ion concentration with respect to the junction depths, vertical ion implantation exhibited concentration profiles as indicated by reference numeral 310, and tilted ion implantation exhibited concentration profiles as indicated by reference numeral 320. In this tilted ion implantation, a tilt angle was set to 7 degrees. By comparison of the concentration profiles between the two ion implantation modes, it can be determined that vertical ion implantation 310 implants impurity ions to a deeper junction depth as compared to tilted ion implantation 320, thus exacerbating channeling effects.

As illustrated in FIG. 4, vertical ion implantation exhibits relatively low sheet resistance with respect to temperatures, as indicated by reference numeral 411, while tilted ion implantation at a tilt angle of 7 degrees exhibits relatively high sheet resistance with respect to the temperature, as indicated by reference numeral 412. Deviations of sheet resistance between vertical ion implantation and tilted ion implantation at a tilt angle of 7 degrees are somewhat lower under increased temperatures, as indicated by reference numeral 420.

As can be seen from graphs of FIGS. 3 and 4, vertical ion implantation exhibits low sheet resistance but presents the problem of channeling effects, whereas tilted ion implantation inhibits channeling effects but exhibits problems associated with high sheet resistance. Thus in vertical ion implantation and tilted ion implantation, there is a trade-off between channeling effects and sheet resistance. Further, given the tremendous shrinkage of the semiconductor devices, shadow effects of photoresist film patterns cause several limitations in performing tilted ion implantation.

### BRIEF SUMMARY OF THE INVENTION

One embodiment of the present invention provides an ion implantation method for manufacturing a semiconductor device that is capable of securing the desired sheet resistance while inhibiting channeling effects. Another embodiment of the present invention to provides a method for fabricating a graded junction using the above-mentioned ion implantation method.

In accordance with one aspect of the present invention an ion implantation method includes implanting a first dose of impurity ions, as part of the total dose of impurity ions to be implanted by vertical ion implantation; and implanting a remaining dose of impurity ions from the total dose by tilted ion implantation.

The tilted ion implantation step may include dividing the remaining dose into a plurality of doses, and implanting the respectively divided doses of impurity ions at different tilt angles.

The tilted ion implantation step may be carried out at an angle of 4°45° degrees between a vertical line relative to the wafer surface and the implantation path of the impurity ions.

The vertical ion implantation and tilted ion implantation steps are preferably carried out under substantially the same ion implantation energy conditions.

The vertical ion implantation and tilted ion implantation steps may be continuously performed using the same ion implantation equipment.

The vertical ion implantation and tilted ion implantation steps may be separately carried out in the same ion implantation equipment.

Impurity ions implanted in the vertical ion implantation and tilted ion implantation steps may include at least one selected from the group consisting of B, P, As, BF₂, BF, In, Sb and Ge.

According to another aspect of the present invention, a method for fabricating a graded junction using an ion implantation method includes implanting impurity ions into a semiconductor substrate by vertical ion implantation to form a first impurity region; and implanting impurity ions into the semiconductor substrate by tilted ion implantation to form a second impurity region which partially overlaps with the first impurity region, the second impurity region having a broader width and shallower depth than the first impurity region.

The dose of the impurity region implanted by vertical ion implantation and the dose of the impurity region implanted by tilted ion implantation are substantially the same.

Ion implantation energy in the vertical ion implantation and tilted ion implantation steps is substantially the same.

The method for fabricating a graded junction of the present invention may further comprise implanting impurity ions into the semiconductor substrate by tilted ion implantation, thereby forming a third impurity region which partially overlaps with the first and second impurity regions, the third impurity region having a broader width and shallower depth than the second impurity region.

In the present invention, the tilt angle of tilted ion implantation for forming the third impurity region is preferably greater than that of tilted ion implantation for forming the second impurity region.

### BRIEF DESCRIPTION OF THE DRAWINGS

FIG. 1 is a view illustrating vertical ion implantation as one example of conventional ion implantation;

FIG. 2 is a view illustrating tilted ion implantation as another example of conventional ion implantation;

FIG. 3 is a graph showing changes in concentrations of impurity ions according to junction depths for respective impurity ions implanted by vertical ion implantation and tilted ion implantation;

FIG. 4 is a graph showing changes in sheet resistance and deviation of sheet resistance with respect to temperatures in impurity regions formed by vertical ion implantation and tilted ion implantation, respectively;

FIG. 5 is a flow chart illustrating an ion implantation method for manufacturing a semiconductor device in accordance with the present invention;

FIGS. 6-8 are views illustrating specific embodiments of an ion implantation method in accordance with the present invention;

FIG. 9 is a graph showing changes in concentrations of impurity ions according to the junction depths of impurity ions implanted by an ion implantation method for manufacturing a semiconductor device in accordance with the present invention;

FIG. 10 is a graph showing sheet resistance with respect to the combination of vertical ion implantation and tilted ion implantation in an ion implantation method for manufacturing a semiconductor device in accordance with the present invention;

FIG. 11 is a cross-sectional view illustrating a method for fabricating graded junctions utilizing an ion implantation method in a semiconductor device in accordance with the present invention;

FIG. 12 is a graph showing peak depths with respect to combination of vertical ion implantation and tilted ion implantation in graded junctions of FIG. 11; and

FIG. 13 is a graph showing peak concentrations with respect to the combination of vertical ion implantation and tilted ion implantation in graded junctions of FIG. 11.

### DETAILED DESCRIPTION OF THE INVENTION

The present invention will now be described more fully with reference to the accompanying drawings hereinafter, in which preferred embodiments of the invention are shown. This invention may, however, be embodied in different forms and should not be construed as limited to the embodiments set forth herein.

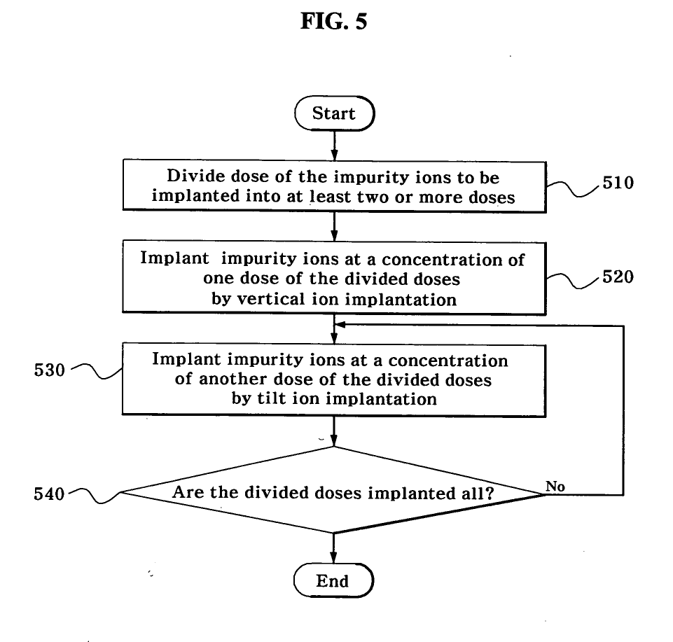

FIG. 5 is a flow chart illustrating an ion implantation method for manufacturing a semiconductor device in accordance with the present invention. The total dose of impurity ions to be implanted is first divided into at least two or more doses (Step 510). For example, the total dose of impurity ions may be divided into two doses, i.e., a first dose and second dose, or may be divided into three doses, i.e., a first dose, second dose and third dose. Under certain applications, the total dose of impurity ions may be divided into four or more doses. The first dose, second dose and third dose may be of the same dose or different doses. Alternatively, some of the doses may have the same does and others may have different doses.

Next, vertical ion implantation (or zero degree tilted ion implantation) is carried out to implant one of the divided doses of impurity ions into a wafer (Step 520). Then, tilted ion implantation is carried out to implant the remaining doses of impurity ions into the wafer (Step 530). When the total dose is divided into two doses, the impurity ions of the first dose are implanted via vertical ion implantation and the impurity ions of the second dose are implanted via tilted ion implantation. When the total dose of impurity ions is divided into three doses, the impurity ions of the first dose are implanted via vertical ion implantation and the impurity ions of the second dose are implanted via tilted ion implantation. In either event, tilted ion implantation is preferably carried out at an angle of 4°-45° degrees between a vertical line relative to the wafer surface and the implantation path of the impurity ions, in order to significantly inhibit the channeling effects.

Next, a determination is made as to whether the divided doses are all implanted or not (Step 540). Where it is determined that the non-implanted doses are still present, the process is returned to Step 530 and a tilted ion implantation is carried out again, but at a different angle than that of the previous tilted ion implantation. When the total dose is divided into two doses, the ion implantation process is complete, since both the first and second doses have been implanted. However, when the total dose of impurity ions is divided into three doses, impurity ions of the remaining third dose are implanted by tilted ion implantation. Where the impurity ions of the second dose are previously implanted by a tilted ion implantation at a first tilt angle, the impurity ions of the third dose are implanted by tilted ion implantation at a second tilt angle, different from the first tilt angle. Alternatively, the third dose may be implanted without any tilt.

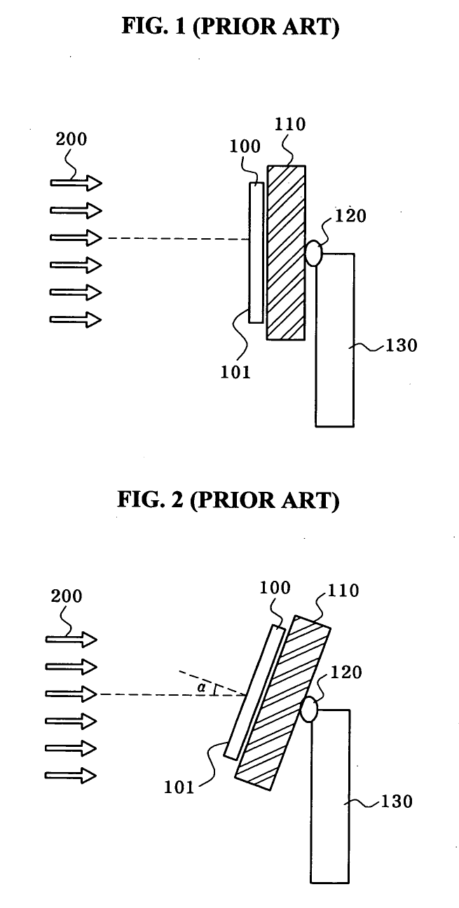

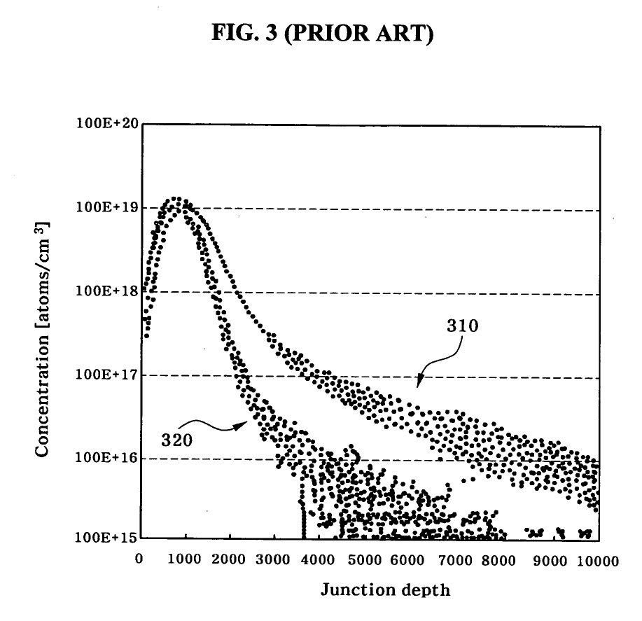

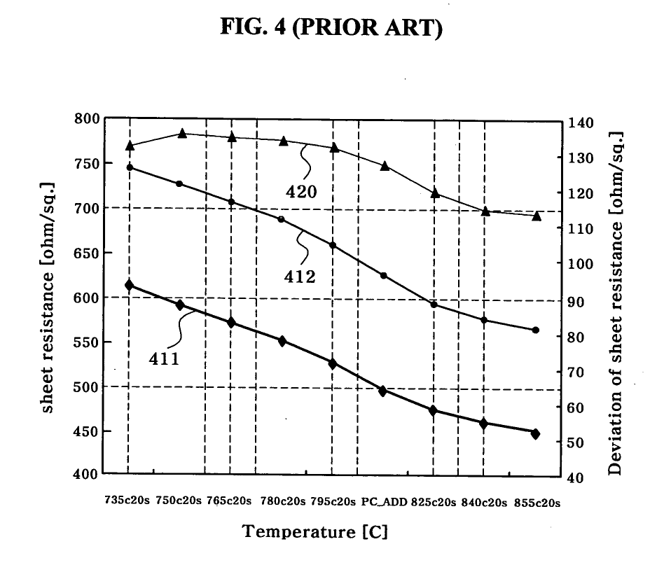

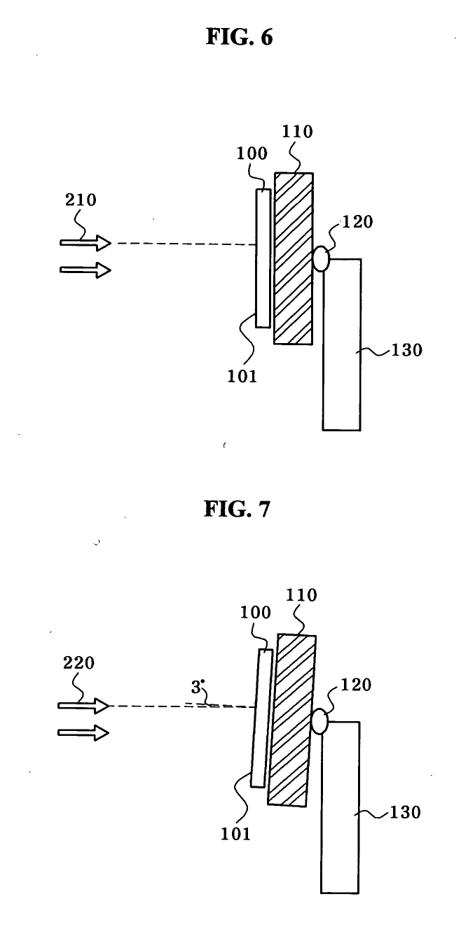

FIGS. 6-8 are views illustrating specific embodiments of an ion implantation method in accordance with the present invention. Hereinafter, like numbers in FIG. 1 refer to like elements in FIGS. 6 through 8, and therefore a description of the similar elements will be omitted.

The present embodiment exemplifies a case in which the total dose of impurity ions to be implanted is 3.0×10¹³ ions/cm³, and is divided into first, second, and third doses having 1.0×10¹³ ions/cm³, respectively. Even though the total dose of impurity ions is divided into three doses in this embodiment, the total dose of impurity ions may be divided into two doses, or may be divided into four or more doses, if desired, as previously described. In addition, even though the total dose of impurity ions is divided into equal doses, at least one of the doses may have a different value.

First, as shown in FIG. 6, a first dose of impurity ions 210 at a density of 1.0×10¹³ ions/cm³ are implanted into the wafer 100 via vertical ion implantation, that is, the wafer 100 is arranged on the wafer support 110, so that a vertical line relative to the front surface 101 of the wafer 100 forms an angle of 0° with the implantation path of the impurity ions 210. Impurity ions 210 are then implanted into the wafer 100 at a density of 1.0×10¹³ ions/cm³.

Next, as shown in FIG. 7, a second dose of impurity ions 210 at a density of 1.0×10¹³ ions/cm³ are implanted into the wafer 100 via tilted ion implantation at a tilt angle of 3°. That is, the wafer 100 is arranged on the wafer support 110, so that a vertical line relative to the front surface 101 of the wafer 100 forms an angle of 3 degrees with the implantation path of the impurity ions 210. Impurity ions 210 are then implanted into the wafer 100 at a density of 1.0×10^{13 ions/cm}³.

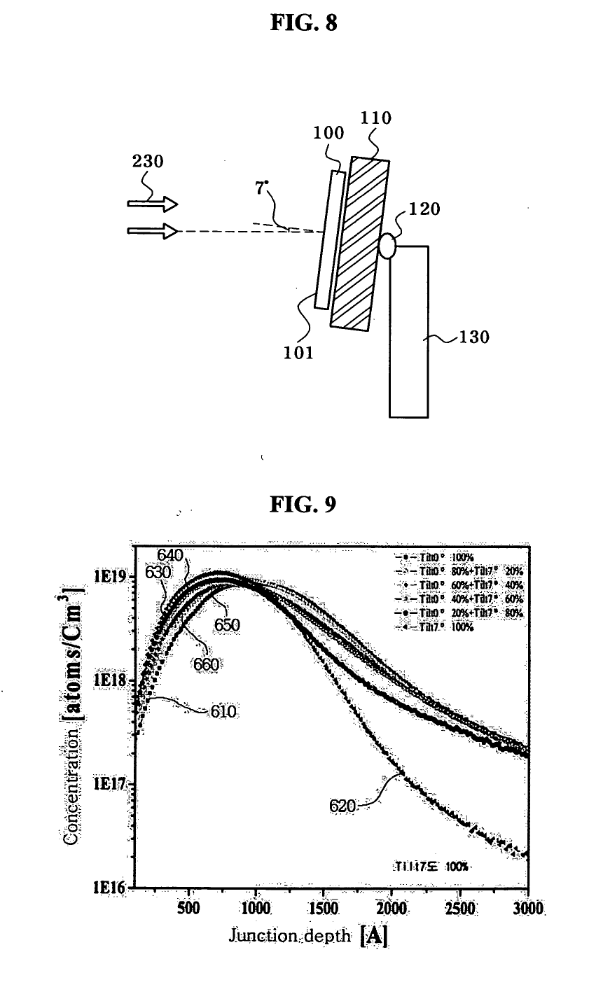

As shown in FIG. 8, a third dose of impurity ions 210 at a density of 1.0×10¹³ ions/cm³ are implanted into the wafer 100 via tilted ion implantation at an angle of 7°. That is, the wafer 100 is arranged on the wafer support 110 so that a vertical line relative to the front surface 101 of the wafer 100 forms an angle of 7° with the implantation path of the impurity ions 210. Impurity ions 210 are then implanted into the wafer 100 at a density of 1.0×10¹³ ions/cm³.

Thus, in implantation of the impurity ions having 3.0×10¹³ ions/cm³ as the total dose, impurity ions 210 at a density of 1.0×10³ ions/cm³ as the first dose are first implanted via vertical ion implantation, impurity ions at a density of 1.0×10¹³ ions/cm³ as the second dose are next implanted via a 3° tilt ion implantation, and finally impurity ions at a density of 1.0×10¹³ ions/cm³ are implanted as the third dose via 7° tilt ion implantation. Such vertical ion implantation, 3° tilt ion implantation and 7° tilt ion implantation are to be performed by the same ion implantation equipment. In this case, the ion implantation processes may be continuously carried out with modification of a process parameter only, or may be independently carried out as separate steps. In addition, taking into consideration consumption of excessive setup time for changing implantation energy in ion implantation equipment, such vertical ion implantation, 3° tilt ion implantation and 7° tilt ion implantation are to be carried out under the same implantation energy conditions in the present embodiment. Impurity ions implanted by the vertical ion implantation, 3° tilt ion implantation and 7° tilt ion implantation may include at least one selected from the group consisting of B, P, As, BF₂, BF, In, Sb and Ge. In addition, such an ion implantation technique can be applied to ion implantation for controlling threshold voltages of devices, ion implantation for formation of sources/drains, ion implantation for formation of wells, and the like.

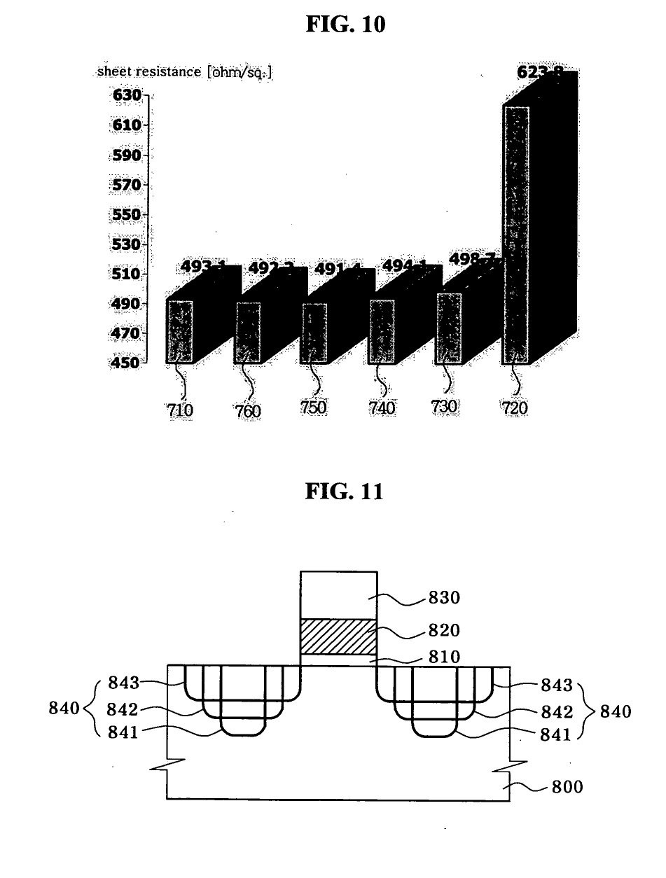

FIG. 9 is a graph showing changes in concentrations of impurity ions with respect to junction depths of impurity ions implanted by an ion implantation method for manufacturing a semiconductor device in accordance with one embodiment of the present invention. FIG. 10 is a graph showing sheet resistance with respect to combination of vertical ion implantation and tilted ion implantation in an ion implantation method for manufacturing a semiconductor device in accordance with one embodiment of the present invention.

Referring to FIG. 9, when vertical ion implantation at a tilt angle of zero degree is carried out alone (i.e., vertical ion implantation 100% and tilted ion implantation 0%) (see the line as indicated by reference numeral 610), the concentration of impurity ions is also high in a region where junction depth is deep, i.e., around 3,000 Å, and therefore problems due to channeling effects may occur. In contrast, when tilted ion implantation at a tilt angle of 7 degrees is carried out alone (i.e., vertical ion implantation 0% and 7 degree-tilted ion implantation 100%) (see the line as indicated by reference numeral 620), the concentration of impurity ions is relatively low in a region where the junction depth is deep, i.e., around 3,000 Å, and therefore occurrence of problems due to channeling effects is inhibited.

Meanwhile, reference numerals 630 through 660 represent combined ion implantation of the vertical ion implantation and 7° tilt ion implantation. Herein, the line indicated by reference numeral 630 represents combined ion implantation of the vertical ion implantation 20% and 7° tilt ion implantation 80%, the line indicated by reference numeral 640 represents combined ion implantation of the vertical ion implantation 40% and 7° tilt ion implantation 60%, the line indicated by reference numeral 650 represents combined ion implantation of the vertical ion implantation 60% and 7° tilt ion implantation 40%, and the line indicated by reference numeral 660 represents combined ion implantation of the vertical ion implantation 80% and 7° tilt ion implantation 20%. Among such combinations of different ion implantation, combined ion implantation of the vertical ion implantation 20% and 7° tilt ion implantation 80% (see the line indicated by 630) exhibits a Rp (Projected Range) similar to that of the vertical ion implantation 100% (see the line indicated by 610), and has a impurity concentration, at a depth of more than 1500 Å, similar to that of 7° tilt ion implantation 100% (see the line indicated by 620). Therefore, it can be seen that combined ion implantation of the vertical ion implantation 20% and 7° tilt ion implantation 80% (see the line indicated by 630) sufficiently inhibits channeling effects.

Referring next to FIG. 10, when vertical ion implantation is carried out alone (see the bar as indicated by reference numeral 710), low sheet resistance of about 493.1 Ω/square is obtained. In contrast, when 7° tilt ion implantation is carried out alone (see the bar as indicated by reference numeral 720), high sheet resistance of about 623.8 Ω/square is obtained. Meanwhile, reference numerals 730 through 760 represent combined ion implantation of the vertical ion implantation and 7° tilted ion implantation. Herein, the bar indicated by reference numeral 730 represents combined ion implantation of the vertical ion implantation 20% and 7° tilt ion implantation 80%, the bar indicated by reference numeral 740 represents combined ion implantation of the vertical ion implantation 40% and 7° tilt ion implantation 60%, the bar indicated by reference numeral 750 represents combined ion implantation of the vertical ion implantation 60% and 7° tilt ion implantation 40%, and the line indicated by reference numeral 760 represents combined ion implantation of the vertical ion implantation 80% and 7° tilt ion implantation 20%. These combinations of vertical ion implantation and 7° tilt ion implantation exhibit sheet resistance values similar to that of 100% vertical ion implantation (bar indicated by 710). In particular, when vertical ion implantation is carried out in combination with 7° tilt ion implantation (see bars 730 through 760), sheet resistance thus obtained is significantly lower when compared to 100% 7° tilt ion implantation (see bar 720). The ratio of vertical ion implantation does not appear to significantly affect the sheet resistance values thus obtained.

FIG. 11 is a cross-sectional view illustrating a method for fabricating graded junctions utilizing an ion implantation method in a semiconductor device in accordance with the present invention. A gate insulating film patterns 810 are disposed on a semiconductor substrate 800, followed by sequential formation of gate conductive film patterns 820 and gate capping film patterns 830. Then, an ion implantation process for forming graded junctions 840 is carried out utilizing certain ion implantation mask film patterns (not shown). First, 0° tilt ion implantation, i.e., vertical ion implantation is carried out. Herein, the concentration of the impurity ions to be implanted is a first dose. Consequently, a first impurity junction 841 having the most narrow width and deepest depth is formed. Next, 3° tilt ion implantation is carried out under substantially the same ion implantation energy and dose conditions as in vertical ion implantation. Consequently, a second impurity junction 842 having a broader width and shallower depth than the first impurity junction 841 is formed. Next, 7° tilt ion implantation is carried out under substantially the same ion implantation energy and dose conditions as in vertical ion implantation and 3° tilt ion implantation. Consequently, a third impurity junction 843 having a broader width and shallower depth than the second impurity junction 842 is formed.

In this manner, by performing vertical ion implantation and at least one or more tilted ion implantation, graded junctions 840 can be formed without changing ion implantation energy conditions, via suitable control of the tilt angle upon performing tilted ion implantation. Such graded junctions may be source/drain regions, as in the present embodiment, or well regions or any other impurity regions in other embodiments.

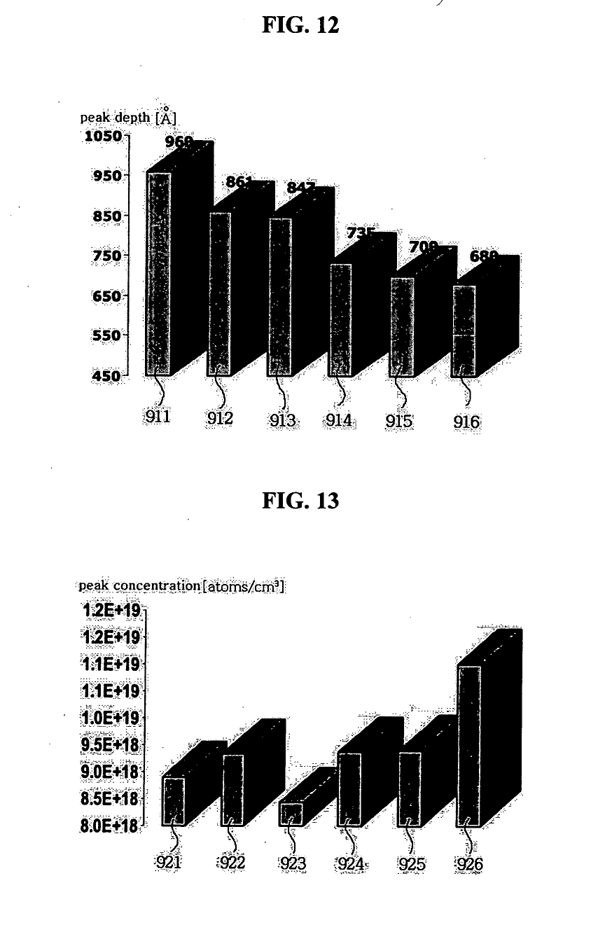

FIG. 12 is a graph showing peak depths with respect to combination of vertical ion implantation and tilted ion implantation in graded junctions of FIG. 11. Whereas, FIG. 13 is a graph showing peak concentrations with respect to combination of vertical ion implantation and tilted ion implantation in graded junctions of FIG. 11.

In FIGS. 12 and 13, bars indicated by reference numerals 911 and 921 represent 0° tilt ion implantation, i.e., 100% vertical ion implantation, respectively. Bars indicated by reference numerals 912 and 922 represent vertical ion implantation 80% +7° tilt ion implantation 20%, respectively. Bars indicated by reference numerals 913 and 923 represent vertical ion implantation 60% +7° tilt ion implantation 40%, respectively. Bars indicated by reference numerals 914 and 924 represent vertical ion implantation 40% +7° tilt ion implantation 60%, respectively. Bars indicated by reference numerals 915 and 925 represent vertical ion implantation 20% +7° tilt ion implantation 80%, respectively. Finally, bars indicated by reference numerals 916 and 926 represent 100% 7° tilt ion implantation, respectively.

As shown in FIGS. 12 and 13, from 100% vertical ion implantation (see bars 911 and 921) through 100% 7° tilt ion implantation (see bars 916 and 926) all showed gradual decreases in peak depths, while peak concentrations were gradually increased in all implantation modes except for the case in which the ratio of vertical ion implantation is 60%. Herein, peak depths and peak concentrations denote depths and concentrations in Rp (Projected Range), respectively.

As apparent from the above description, in accordance with the ion implantation method for manufacturing a semiconductor device of the present embodiment and a method for fabricating a graded junction using the same, it is possible to obtain the desired sheet resistance while sufficiently inhibiting the channeling effects, by combined ion implantation of vertical ion implantation at an angle of zero degrees and tilted ion implantation at a given tilt angle.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. An ion implantation method, comprising:
implanting a first dose of impurity ions into a substrate as part of the total dose of the impurity ions to be implanted into the substrate; and
implanting a second dose of the impurity ions into the substrate as part of the total dose,
wherein one of the first and second doses is implanted using a vertical ion implantation step and another of the first and second doses is implanted using a tilted ion implantation step.

2. The method according to claim 1, further comprising:
implanting a third dose of the impurity ions into the substrate as part of the total dose using a tilted ion implantation step having a different tilt the other tilted ion implantation step.

3. The method according to claim 1, wherein the tilted ion implantation step is carried out at an angle of 4 to 45 degrees, the angle being an angle defined by a plane that is orthogonal to a substrate surface and an implantation path of the impurity ions.

4. The method according to claim 1, wherein the vertical ion implantation and tilted ion implantation steps are carried out under substantially the same ion implantation energy conditions.

5. The method according to claim 1, wherein the vertical ion implantation and tilted ion implantation steps are continuously carried out in the same ion implantation equipment.

6. The method according to claim 1, wherein the vertical ion implantation and tilted ion implantation steps are separately carried out in the same ion implantation equipment.

7. The method according to claim 1, wherein impurity ions implanted in the vertical ion implantation and tilted ion implantation steps include at least one selected from the group consisting of B, P, As, BF², BF, In, Sb and Ge.

8. A method for fabricating a graded junction, comprising:
performing a first implantation step to implant first dopants into a surface of a semiconductor substrate at a substantially orthogonal direction with respect to the surface of the substrate to form a first dopant region; and
performing a second implantation step to implant second dopants into the substrate at a first given angle with respect to a plane that is orthogonal to the surface of the substrate to form a second dopant region,
wherein the second dopant region at least partially overlaps the first impurity region and has a broader width and shallower depth than the first dopant region.

9. The method according to claim 8, wherein the first dopant region and the second dopant region have substantially the same dopant concentration.

10. The method according to claim 8, wherein the first and second implantation steps use substantially the same implantation energy.

11. The method according to claim 8, further comprising:
performing a third implantation step to implant third dopants into the surface of the substrate at a second given angle with respect to the orthogonal plane to form a third dopant region, wherein the third dopant region at least partially overlaps the first and second impurity regions and has a broader width and shallower depth than the second dopant region.

12. The method according to claim 11, wherein the second given angle is greater than the first given angle.

13. The method according to claim 8, wherein the first and second dopants are the same.

14. The method according to claim 8, wherein the first and second dopants are different.

15. The method according to claim 8, wherein the first implantation step is performed before the second implantation step.

16. The method according to claim 8, wherein the second implantation step is performed before the first implantation step.

17. The method according to claim 8, wherein the first and second regions have substantially the same dopant concentration.

18. The method according to claim 8, wherein the first and second regions have different dopant concentrations.

19. The method according to claim 8, wherein the first and second region comprise a source or drain region.
